(19) United States
(12) Patent Application Publication
(10) Pub. No.: US 2007/0063295 A1
(43) Pub. Date: Mar. 22, 2007

(54) Gate electrode, method of forming the same, transistor having the gate electrode, method of manufacturing the same, semiconductor device having the gate electrode and method of manufacturing the same

(75) Inventors: In-Sang Jeon, Seoul (KR); Yu-Gyun Shin, Seongnam-si (KR); Sang-Bom Kang, Seoul (KR); Hong-Bae Park, Yeongdeungpo-gu (KR); Hye-Min Kim, Suwon-si (KR); Beom-Jun Jin, Seoul (KR)

Correspondence Address: HARNESS, DICKEY & PIERCE, P.L.C., P.O. BOX 8910, RESTON, VA, 20195, US

(73) Assignee: Samsung Electronics Co.,Ltd.

(21) Appl. No.: 11/522,343

(22) Filed: Sep. 18, 2006

(30) Foreign Application Priority Data
Sep. 20, 2005 (KR) 2005-87215

(51) Int. Cl. H01L 29/94

(52) U.S. Cl. 257/410; 257/E29.297

(57) ABSTRACT

Example embodiments relate to a gate electrode, a method of forming the gate electrode, a transistor having the gate electrode, a method of manufacturing the transistor, a semiconductor device having the transistor and a method of manufacturing the semiconductor device. The gate electrode may include an embossing structure including a metal or a metal compound and having a first work function and a conductive layer pattern having a second work function formed on the embossing structure. A work function of the gate electrode may be adjusted between a work function of the embossing structure and a work function of the conductive layer pattern formed on the embossing structure. An NMOS transistor and a PMOS transistor having different work functions respectively may be formed on a substrate.

### PRIORITY STATEMENT

This application claims priority under 35 USC § 119 to Korean Patent Application No. 2005-87215 filed on Sep. 20, 2005, in the Korean Intellectual Property Office (KIPO), the entire contents of which are herein incorporated by reference.

### BACKGROUND

1. Field of the Invention

Example embodiments relate to a gate electrode, a method of forming the same, a transistor having the gate electrode, a method of manufacturing the same, a semiconductor device having the gate electrode, and a method of manufacturing the same.

2. Description of the Related Art

A transistor of the semiconductor device may include a gate electrode formed on an active region of a semiconductor substrate, a gate insulation layer formed between the gate electrode and the semiconductor substrate, and source and drain regions formed in the active region adjacent to the gate electrode. The latest semiconductor devices may include a metal-oxide semiconductor field effect transistor (MOSFET). The transistor may be classified into an N-type channel MOS (NMOS) transistor and/or a P-type channel MOS (PMOS) transistor corresponding to a main carrier migrating along a channel. In order to meet the demands of having a higher performance speed and electrical efficiency, the MOS type semiconductor devices may include a complementary MOS (CMOS) type transistor including the NMOS transistor and the PMOS transistor.

The gate electrode in the conventional CMOS transistor may be formed using polysilicon. When the gate electrode in the semiconductor device having a fine design rule is formed using polysilicon, a thickness of the gate insulation layer may electrically increase and boron penetration phenomenon may occur due to a depletion of polysilicon. Methods of forming the gate electrode using a metal have been considered as an alternative. In order to substitute a conventional polysilicon electrode, a metal having a work function of about 4.1 eV to about 4.3 eV proper for the NMOS transistor and a metal having a work function of about 4.8 eV to about 5.1 eV proper for the PMOS transistor may be applied to the semiconductor device. The metal having a work function of the above-mentioned range may be difficult to select.

Methods of forming the gate electrode using a two-component metal complex (e.g., MoN, NiSi, TaN and/or WN) or a three-component metal complex (e.g., TiSiN, TaSiN and/or MoSiN) have been attempted. According to the conventional art, an NMOS transistor including a tungsten complex (WAx, A is Ta, Nb or Ti) layer having a work function of about 4.2 eV to about 4.4 eV and a tungsten (W) layer and a PMOS transistor including a tungsten complex (WBx, B is Mo, Ni or Pt) layer having a work function of about 4.7 eV to about 5.2 eV and a tungsten (W) layer may be disclosed. A proper metal having a desirable work function may be selected, but the melting point of the metal may be lower. The metal may also be more readily oxidized or the crystal structure of the metal may be changed according to the temperature. The work function of the metal may change according to the above conditions. When the gate electrode for the NMOS transistor and the PMOS transistor have different heights respectively, a subsequent process (e.g., a planarization process) of the gate electrode may be more difficult to perform.

### SUMMARY

Example embodiments relate to a gate electrode, a method of forming the same, a transistor having the gate electrode, a method of manufacturing the same, a semiconductor device having the gate electrode, and a method of manufacturing the same.

Example embodiments provide a gate electrode having improved electrical characteristics. According to example embodiments, the gate electrode may include an embossing structure including a metal or a metal compound having a first work function and a conductive layer pattern having a second work function formed on the embossing structure. The embossing structure may include discontinuous island-like structures. In example embodiments, the gate electrode may have a work function substantially greater than the second work function and substantially smaller than the first work function.

In example embodiments, the embossing structure may include copper (Cu), germanium (Ge), ruthenium (Ru), tungsten (W) and/or chromium (Cr). The conductive layer pattern may include polysilicon doped with N-type impurities. The conductive layer pattern may include iron (Fe), magnesium (Mg), cobalt (Co), aluminum (Al), titanium (Ti), zirconium (Zr), hafnium (Hf), lead (Pb), nickel (Ni), platinum (Pt), palladium (Pd), rhodium (Rh) and/or selenium (Se). In example embodiments, the gate electrode may have a work function substantially greater than the first work function and substantially smaller than the second work function. In other example embodiments, the embossing structure may include copper (Cu), germanium (Ge), ruthenium (Ru), tungsten (W) and/or chromium (Cr). The conductive layer pattern may include polysilicon doped with P-type impurities. The conductive layer pattern may include nickel (Ni), platinum (Pt), palladium (Pd), rhodium (Ru), iridium (Ir) and/or selenium (Se).

According to still other example embodiments, there is provided a method of forming a gate electrode. In the method, an embossing structure including a metal or a metal compound and having a first work function may be formed. A conductive layer pattern having a second work function may be formed on the embossing structure. The embossing structure may be formed by an electron-beam (e-beam) evaporation deposition process. In example embodiments, the embossing structure may include copper (Cu), germanium (Ge), ruthenium (Ru), tungsten (W) and/or chromium (Cr). The conductive layer pattern may include polysilicon with N-type impurities or polysilicon with P-type impurities. The conductive layer pattern may include iron (Fe), magnesium (Mg), cobalt (Co), aluminum (Al), titanium (Ti), zirconium (Zr), hafnium (Hf), lead (Pb), nickel (Ni), platinum (Pt), palladium (Pd), rhodium (Rh) and/or selenium (Se).

According to still other example embodiments, there is provided a transistor. The transistor may include a substrate, a gate insulation layer pattern formed on the substrate, the gate electrode and an impurity region formed in the substrate adjacent to the gate electrode.

According to still other example embodiments, there is provided a method of manufacturing a transistor. In the method, a gate insulation layer pattern may be formed on a substrate. The gate electrode may be formed on the gate insulation layer pattern. An impurity region may be formed by implantation impurities in the substrate adjacent to the gate electrode.

According to still other example embodiments, there is provided a semiconductor device. The semiconductor device may include a substrate, a first conductive region and a second conductive region formed on the substrate, a first gate insulation layer pattern and a second gate insulation layer pattern formed on the first and the second conductive regions, respectively, and a first gate structure and a second gate structure, including a first gate electrode and a second gate electrode, formed on the first and the second gate insulation layer patterns.

Embossing structures of the first and the second gate electrodes may have a first work function and a third work function, and conductive layer patterns of the first and the second gate electrodes have a second work function and a fourth work function, respectively. The first gate electrode may have a work function in a range of the second work function to the first work function and the second gate electrode may have a work function in a range of the third work function to the fourth work function. The conductive layer pattern of the first gate electrode may include polysilicon doped with N-type impurities and the conductive layer pattern of the second gate electrode may include polysilicon doped with P-type impurities. The first and the second gate insulation layer patterns may include high-k materials.

Further, a first nitride layer pattern may be formed on the first gate insulation layer pattern and a second nitride layer pattern may be formed on the second gate insulation layer pattern. The conductive layer pattern of the first gate electrode may include iron (Fe), magnesium (Mg), cobalt (Co), aluminum (Al), titanium (Ti), zirconium (Zr), hafnium (Hf) and/or lead (Pb). The conductive layer pattern of the second gate electrode may include at least one selected from the group including nickel (Ni), platinum (Pt), palladium (Pd), rhodium (Rh) and/or selenium (Se).

According to still other example embodiments, there is provided a method of manufacturing a semiconductor device. In the method, a first conductive region and a second conductive region may be formed on a substrate. A first gate insulation layer pattern and a second gate insulation layer pattern may be formed on the first and the second conductive regions, respectively. A first gate structure and a second gate structure, including a first gate electrode and a second gate electrode, may be formed on the first and the second gate insulation layer patterns. Embossing structures of the first and the second gate electrodes may have a first work function and a third work function, and conductive layer patterns of the first and the second gate electrodes may have a second work function and a fourth work function, respectively. The first gate electrode may have a work function substantially greater than the second work function and substantially smaller than the first work function and the second gate electrode may have a work function substantially greater than the third work function and substantially smaller than the fourth work function.

According to example embodiments, in a formation of a gate electrode of a transistor, the gate electrode may include an embossing structure including a metal or a metal compound having discontinuous island-like structures. A work function of the gate electrode may be controlled by a thickness of the embossing structure. The work function of the gate electrode may be adjusted between a work function of the embossing structure and a work function of a conductive layer pattern formed on the embossing structure. The conductive layer pattern may be formed using polysilicon and/or a metal. An NMOS transistor and a PMOS transistor having different work functions respectively may be formed on a substrate.

### BRIEF DESCRIPTION OF THE DRAWINGS

Example embodiments will be more clearly understood from the following detailed description taken in conjunction with the accompanying drawings. FIGS. 1-9C represent non-limiting, example embodiments as described herein.

FIGS. 1 to 2 are diagrams illustrating a transistor in accordance with example embodiments;

FIGS. 3A to 3E are diagrams illustrating a method of manufacturing a transistor in accordance with example embodiments;

FIG. 4 to 6 are graphs illustrating a relation between a flat band voltage of a gate electrode and a thickness of an embossing structure in accordance with example embodiments;

FIG. 7 is a diagram illustrating a semiconductor device including a complementary metal-oxide semiconductor (CMOS) transistor in accordance with example embodiments;

FIGS. 8A to 8F are diagrams illustrating a method of manufacturing a semiconductor device including a CMOS transistor in accordance with example embodiments; and

FIGS. 9A to 9C are diagrams illustrating a method of manufacturing a semiconductor device including a CMOS transistor in accordance with example embodiments.

### DESCRIPTION OF THE EXAMPLE EMBODIMENTS

Various example embodiments are described more fully hereinafter with reference to the accompanying drawings, in which example embodiments are shown. Example embodiments may, however, be embodied in many different forms and should not be construed as limited to the example embodiments set forth herein. Rather, these example embodiments are provided so that this disclosure will be thorough and complete and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. A first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relation to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Example embodiments are described herein with reference to cross-section illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a gate electrode, a method of forming the gate electrode, a transistor having the gate electrode, a method of manufacturing the transistor, a semiconductor device having the transistor and a method of manufacturing the semiconductor device. Other example embodiments relate to a gate electrode having improved electrical characteristics, a method of forming the gate electrode, a transistor having the gate electrode, a method of manufacturing the transistor, a semiconductor device having the transistor and a method of manufacturing the semiconductor device.

Transistor and a Method of Manufacturing the Transistor

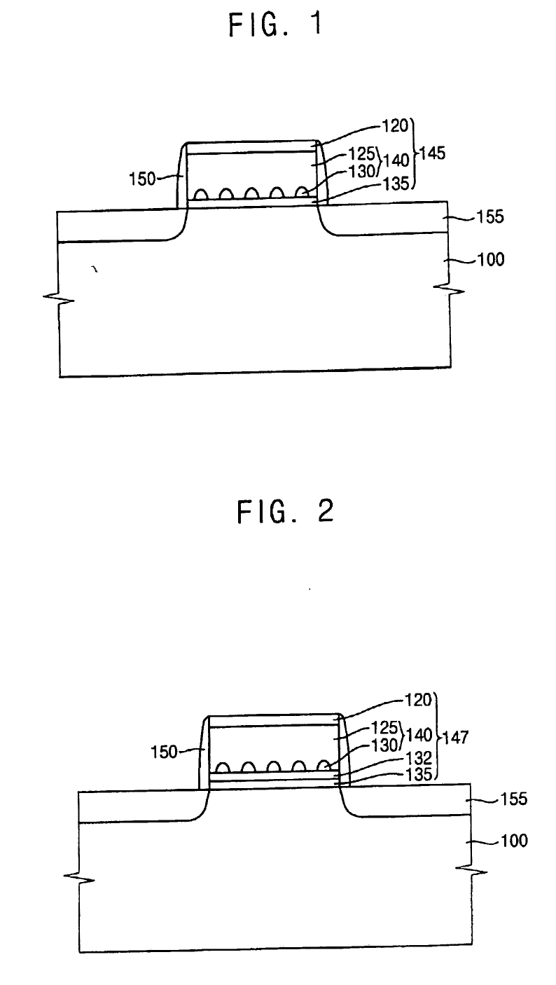

FIG. 1 is a diagram illustrating a transistor in accordance with example embodiments. Referring to FIG. 1, a transistor may include a gate structure 145, a spacer 150 and impurity regions 155. The gate structure 145 may include a gate insulation layer pattern 135, a gate electrode 140 and a gate mask 120 formed on a substrate 100. The spacer 150 may be formed on a sidewall of the gate structure 145. The impurity regions 155 may be formed on surface portions of the substrate 100 adjacent to the gate structure 145.

The gate electrode 140 may include an embossing structure 130 having a first work function and a conductive layer pattern 125 having a second work function. The embossing structure 130 may include a metal or a metal compound. In example embodiments, the embossing structure 130 may include discontinuous island-like structures. The embossing structure 130 may be formed on the gate insulation layer pattern 135. The conductive layer pattern 125 may be formed on the embossing structure 130. An isolation layer (not shown) may be formed in the substrate 100. An active region and a field region may be defined by the isolation layer. The substrate 100 may include a silicon wafer and/or a silicon-on-insulator (SOI) substrate.

The gate insulation layer pattern 135 may be formed on the active region of the substrate 100. The gate insulation layer pattern 135 may include silicon oxide and/or a high-k material (e.g., a metal oxide). The gate insulation layer pattern 135 may include a metal oxide (e.g., tantalum oxide, titanium oxide, hafnium oxide, zirconium oxide, aluminum oxide, hafnium aluminum oxide, yttrium oxide, niobium oxide, cesium oxide, indium oxide, lanthanum oxide and/or any other suitable metal oxide) or a metal oxynitride (e.g., aluminum oxynitride, hafnium oxynitride and/or any other suitable metal oxynitride). These may be used alone or in a mixture thereof. When the gate insulation layer pattern 135 includes the metal oxide, the gate insulation layer pattern 135 may have a thin equivalent oxide thickness (EOT). A leakage current between the gate electrode 140 and the impurity regions 155 may be more sufficiently reduced.

The embossing structure 130 of the gate electrode 140 may be formed on the gate insulation layer pattern 135. In example embodiments, the embossing structure 130 may include discontinuous island-like structures. The embossing structure 130 may have a first work function. Sizes of the island-like structures may be in a range of about 0.5 nm to about 5 nm. The conductive layer pattern 125 may be formed on the embossing structure 130. The conductive layer pattern 125 may include polysilicon doped with impurities or a metal. The conductive layer pattern 125 may have a second work function. The conductive layer pattern 125 may include a metal (e.g., iron (Fe), magnesium (Mg), cobalt (Co), aluminum (Al), titanium (Ti), zirconium (Zr), hafnium (Hf), lead (Pb), nickel (Ni), platinum (Pt), palladium (Pd), rhodium (Rh), selenium (Se) and/or any other suitable metal).

A work function of the gate electrode 140 may be determined between the first work function of the embossing structure 130 and the second work function of the conductive layer pattern 125. In example embodiments, the work function of the gate electrode 140 may change to correspond with a thickness of the embossing structure 130. The gate electrode 140 having a desirable work function may be formed by controlling the thickness of the embossing structure 130.

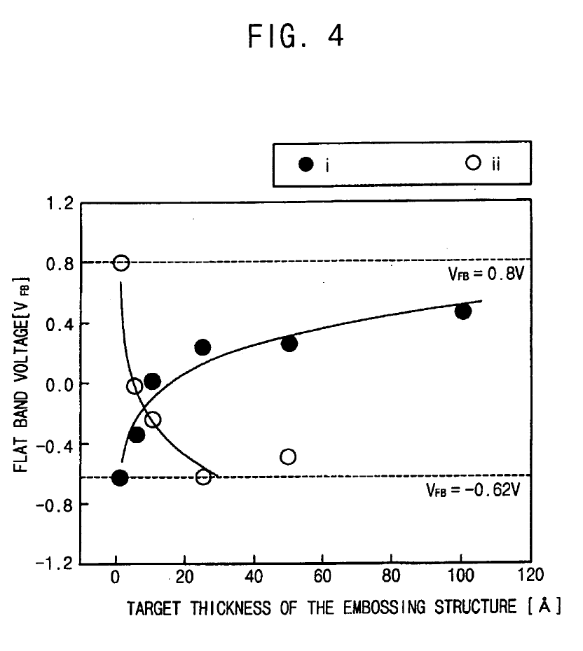

FIG. 4 is a graph illustrating a relation between a flat band voltage of the gate electrode 140 and a thickness of the embossing structure 130 in accordance with example embodiments. In FIG. 4, the X-axis represents the thickness of the embossing structure 130. The thickness of the embossing structure 130 may not be an actual thickness. The thickness of the embossing structure 130 in FIG. 4 means a target thickness that is calculated when the embossing structure 130 may be deposited by a desired deposition rate. The Y-axis in FIG. 4 represents a flat band voltage of the gate electrode 140.

Referring to FIG. 4, the flat band voltage of the gate electrode 140 may be changed according to the thicknesses of the embossing structure 130 and the conductive layer pattern 125. A graph represented by “i” is when the embossing structure 130 includes platinum and the conductive layer pattern 125 includes titanium. A graph represented by “ii” is when the embossing structure 130 includes titanium and the conductive layer pattern 125 includes platinum. The flat band voltage is in a range of about −0.62V to about 0.8V. In the graph “i” when a target thickness of the embossing structure 130 is about 0 Å, the flat band voltage is about −0.62V. The flat band voltage is increased in proportion to the target thickness of the embossing structure 130. In the graph “ii,” when a target thickness of the embossing structure 130 is about 0 Å, the flat band voltage is about 0.8V. The flat band voltage may be decreased in inverse proportion to the target thickness of the embossing structure 130.

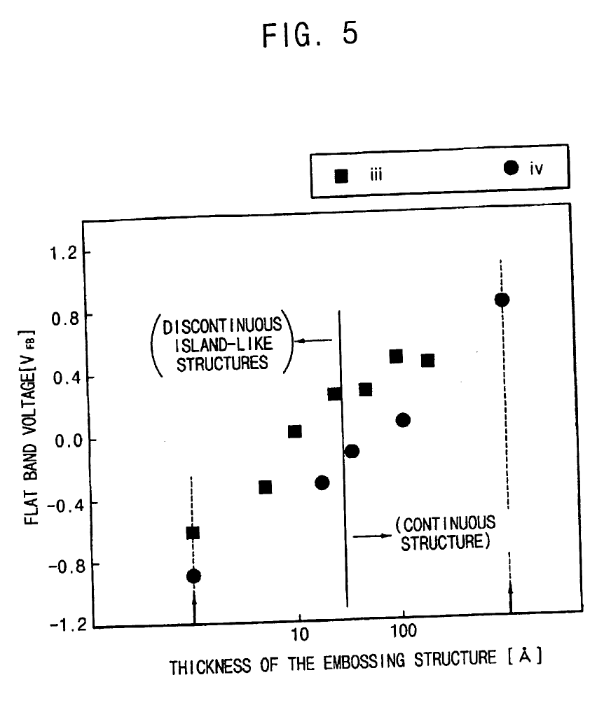

FIG. 5 is a graph illustrating a relation between a flat band voltage of the gate electrode 140 and a thickness of the embossing structure 130 in accordance with example embodiments. In FIG. 5, the X-axis represents the thickness of the embossing structure 130 when the embossing structure 130 is formed using platinum. Referring to FIG. 5, the flat band voltage of the gate electrode 140 may be proportional to the thickness of the embossing structure 130. The embossing structure 130 includes platinum. A graph represented by “iii” is when a conductive layer pattern 125 includes titanium. A graph represented by “iv” is when the conductive layer pattern 125 includes aluminum.

When the embossing structure 130 is formed by a deposition process (e.g., an electron-beam (e-beam) evaporation deposition process) using a metal, the discontinuous island-like structures may be formed at an early stage of deposition. When a deposition process maintains a desired thickness, the discontinuous island-like structures may become a continuous structure. A thickness of the continuous structure, which is converted from the discontinuous island-like structure, may be varied depending on the kind of metal. The flat band voltage may be linearly changed according to the thickness of the embossing structure 130 and independent of a transition into the continuous structure. The flat band voltage may be changed in the early stage of deposition. When the embossing structure 130 includes the discontinuous island-like structures before becoming the continuous structure, the work function of the gate electrode 140 may be controlled by the embossing structure 130.

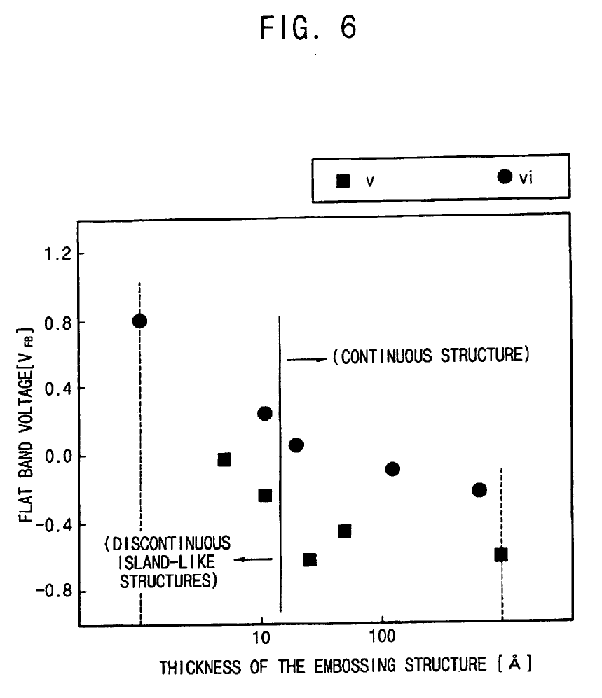

FIG. 6 is a graph illustrating a relation between a flat band voltage of the gate electrode 140 and a thickness of the embossing structure 130 according to example embodiments. In FIG. 6, the X-axis represents the thickness of the embossing structure 130 when the embossing structure 130 is formed using titanium or tantalum. Referring to FIG. 6, a graph represented by “v” is when the embossing structure 130 is formed using titanium. A graph represented by “vi” is when the embossing structure 130 is formed using tantalum. The flat band voltage is in inverse proportion to the thickness of the embossing structure 130.

Referring to FIGS. 4 to 6, the gate electrode 140 having a work function proper for an NMOS transistor or a PMOS transistor may be formed by controlling the thickness of the embossing structure 130. In example embodiments, the work function of the gate electrode 140 may be changed when the embossing structure 130 includes discontinuous island-like structures at an early stage of deposition. The gate electrode 140 having a desirable work function may be formed by controlling the thickness of the embossing structure 130. The embossing structure 130 may not be thickened in order to form the gate electrode 140 having the desirable work function.

The gate electrode 140 of an NMOS transistor may have a work function of about 4.1 eV to about 4.7 eV. In example embodiments, the embossing structure 130 may include a metal or a metal compound (e.g., a metal nitride, a metal carbide, a metal carbonitride and/or any other suitable metal or metal compound) having a work function of about 4.4 eV to about 4.7 eV. The conductive layer 125 may include polysilicon doped with first impurities on the embossing structure 130. The metal having the work function of about 4.4 eV to about 4.7 eV may include copper (Cu), germanium (Ge), ruthenium (Ru), tungsten (W), chromium (Cr) and/or any other suitable metal. The first impurities may include phosphorus (P).

In other example embodiments, the embossing structure 130 may include a metal or a metal compound having a work function of about 4.4 eV to about 4.7 eV. The conductive layer pattern 125 may include a metal or a metal compound having a work function of about 3 eV to about 4.6 eV. Examples of the metal having the work function of about 3 eV to about 4.6 eV may include iron (Fe), magnesium (Mg), cobalt (Co), aluminum (Al), titanium (Ti), zirconium (Zr), hafnium (Hf), lead (Pb) and/or any other suitable metal. In still other example embodiments, the embossing structure 130 may include a metal or a metal compound having a work function of about 3 eV to about 5 eV. The conductive layer pattern 125 may include a metal or a metal compound having a work function of about 1.5 eV to about 4.6 eV.

The gate electrode 140 of a PMOS transistor may have a work function of about 4.7 eV to about 5.2 eV. In example embodiments, the embossing structure 130 may be formed using a metal or a metal compound (e.g., a metal nitride, a metal carbide, a metal carbonitride and/or any other suitable metal or metal compound) having a work function of about 4.4 eV to about 4.7 eV. The conductive layer 125 may be formed using polysilicon doped with second impurities on the embossing structure 130. The second impurities may include boron (B) and/or boron fluoride (BF₂). The gate electrode 140 may have a work function of about 4.7 eV to about 5.2 eV which is proper for the NMOS transistor according to a concentration of the second impurities.

In other example embodiments, the embossing structure 130 may be formed using a metal or a metal compound having a work function of about 4.4 eV to about 4.7 eV. The conductive layer 125 may be formed using a metal or a metal compound (e.g., a metal nitride, a metal carbide, a metal carbonitride and/or any other suitable metal or metal compound) having a work function of about 4.6 eV to about 6 eV. The metal having the work function of about 4.6 eV to about 6 eV may include nickel (Ni), platinum (Pt), palladium (Pd), rhodium (Ru), iridium (Ir), selenium (Se) and/or any other suitable metal. In still other example embodiments, the embossing structure 130 may include a metal or a metal compound (e.g., a metal nitride, a metal carbide, a metal carbonitride and/or any other suitable metal or metal compound) having a work function of about 3 eV to about 5 eV. The conductive layer pattern 125 may include a metal or a metal compound (e.g., a metal nitride, a metal carbide, a metal carbonitride and/or any other suitable metal or metal compound) having a work function of about 4.6 eV to about 6.5 eV.

When the gate electrode 140 is formed by the above methods, the embossing structure 110 and the conductive layer 125 may be formed using various materials according to a desirable semiconductor device and a manufacturing process of the semiconductor device. The gate electrode 140 having a desirable work function may be formed by controlling a thickness of the embossing structure 130.

Referring again to FIG. 1, a gate mask 120 is formed on the gate electrode 140. The gate mask 120 may include a material having an etching selectivity relative to those of the gate electrode 140 and an oxide. For example, the gate mask 120 may include a nitride (e.g., silicon nitride) or an oxynitride (e.g., silicon oxynitride). A spacer 150 may be formed on a sidewall of the gate structure 145. The spacer 150 may include a material having an etching selectivity relative to those of the gate electrode 140 and an oxide. For example, the spacer 150 may include a nitride (e.g., silicon nitride) or an oxynitride (e.g., silicon oxynitride). Impurity regions 155 may be formed at surface portions of the substrate 100 adjacent to the gate structure 145. The impurity regions 155 may include N-type impurities or P-type impurities. When the transistor is a MOS transistor, the impurity regions 155 may correspond to source and drain regions.

FIG. 2 is a diagram illustrating a transistor in accordance with other example embodiments. Referring to FIG. 2, a transistor may include a gate structure 147, a spacer 150 and impurity regions 155. The gate structure 147 may include a gate insulation layer pattern 135, a nitride layer pattern 132, a gate electrode 140 and a gate mask 120. The gate electrode 140 may include an embossing structure 130 and a conductive layer pattern 125.

In example embodiments, the nitride layer pattern 132, including silicon nitride, may be further formed on the gate insulation layer 135. The nitride layer pattern 132 may serve to relieve Fermi level pinning phenomenon. When the gate electrode 140 including polysilicon doped with impurities is formed on the gate insulation layer pattern 135 including a high-k material, the gate electrode 140 may have a Fermi level different from that of the gate electrode 140 formed on a silicon oxide layer. Because of the Fermi level pinning phenomenon, the flat band voltage may be difficult to control by a concentration of doping impurities into the gate electrode 140. A MOS transistor having a desirable work function may be more difficult to form. The Fermi level pinning phenomenon may be more obvious in a formation of a PMOS transistor. The nitride layer pattern 132 formed on the gate insulation layer 135 may relieve the Fermi level pinning phenomenon. The nitride layer pattern 132 may serve to retard, or prevent, impurities of the conductive layer pattern 125 from penetrating into the substrate 100. For example, the nitride layer pattern 132 may serve as a barrier layer for retarding, or preventing, a boron penetration.

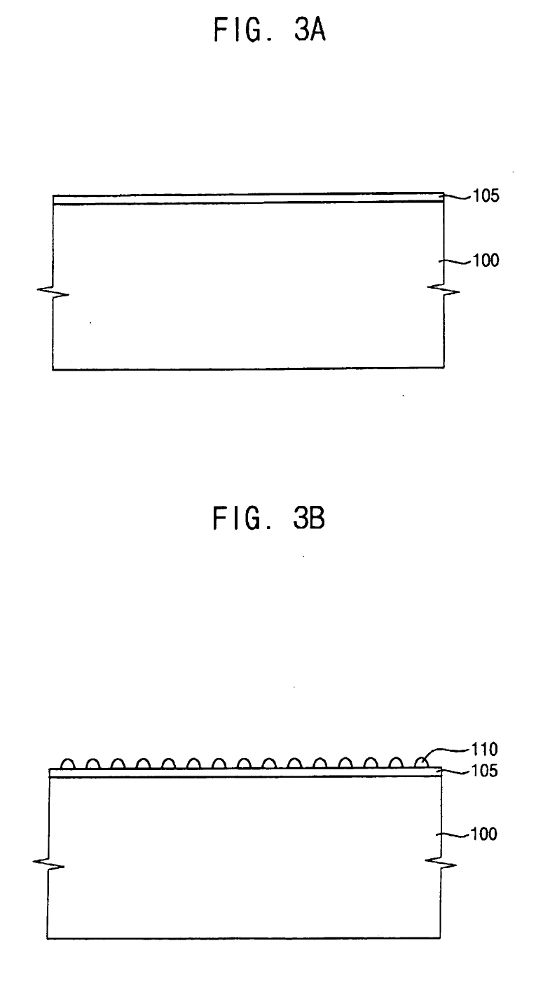

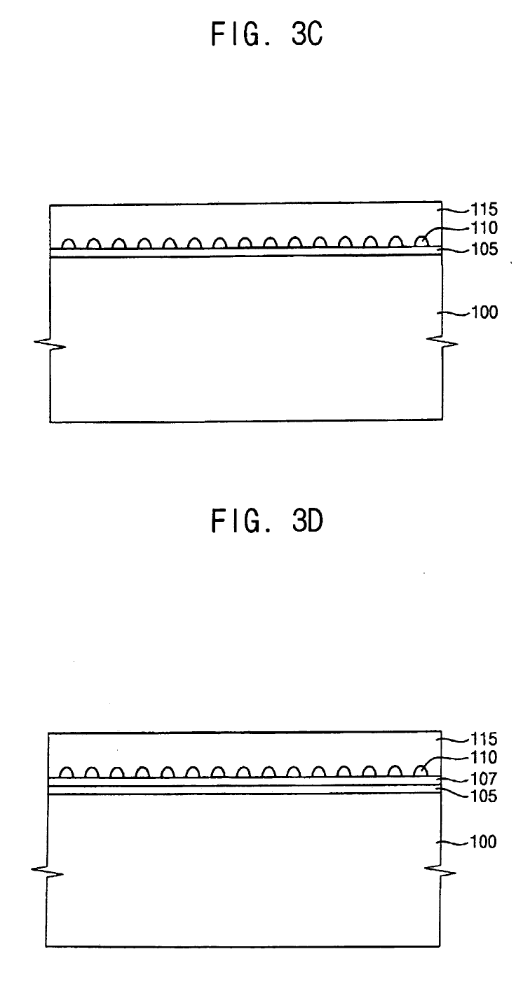

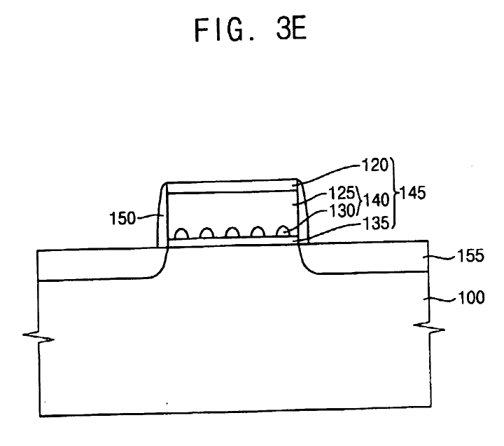

FIGS. 3A to 3E are diagrams illustrating a method of manufacturing a transistor according to example embodiments. Referring to FIG. 3A, an isolation layer (not shown) may be formed in a substrate 100 by an isolation process (e.g., a shallow trench isolation (STI) process) to define an active region and a field region. The substrate 100 may include a silicon wafer or a silicon-on-insulator (SOI) substrate. A gate insulation layer 105 may be formed on the active region of the substrate 100. In example embodiments, the gate insulation layer 105 may be formed using silicon oxide. The gate insulation layer 105 may be formed by a rapid thermal oxidation process, a furnace thermal oxidation process, a plasma oxidation process and/or any other suitable process.

In other example embodiments, the gate insulation layer 105 may be formed using a high-k material (e.g., a metal oxide). The gate insulation layer 105 may be formed by a chemical vapor deposition (CVD) process, a physical vapor deposition (PVD) process, a sputtering process and/or any other suitable process. The high-k material may include a metal oxide (e.g., tantalum oxide, titanium oxide, hafnium oxide, zirconium oxide, aluminum oxide, hafnium aluminum oxide, yttrium oxide, niobium oxide, cesium oxide, indium oxide, lanthanum oxide and/or any other suitable metal oxide) or a metal oxynitride (e.g., aluminum oxynitride, hafnium oxynitride and/or any other suitable metal oxynitride). These may be used alone or in a mixture thereof.

Referring to FIG. 3B, a preliminary embossing structure 110 may be formed on the gate insulation layer 105. The preliminary embossing structure 110 may include discontinuous island-like structures. The preliminary embossing structure 110 may be formed by an electron-beam (e-beam) evaporation deposition process, a sputtering process, a thermal evaporation deposition process, a laser molecular beam epitaxy (L-MBE) deposition process, a pulsed laser deposition (PLD) process and/or any other suitable deposition process. In example embodiments, the preliminary embossing structure 10 may be formed by an e-beam evaporation deposition process. The e-beam evaporation deposition process may be performed by spraying a material on a rotating substrate in a chamber using an electron gun. In the e-beam evaporation deposition process, a deposition rate may be more easily controlled. The e-beam evaporation deposition process may be performed within a wide range of varying temperatures. The material deposited by the e-beam evaporation deposition process may be more pure and have an improved adhesiveness to the substrate 100.

When the preliminary embossing structure 110 is formed by the e-beam evaporation deposition process using a metal, the discontinuous island-like structures having sizes of about 0.5 nm to about 5 nm may be formed at an early stage of deposition. When a deposition process maintains a desired thickness of the preliminary embossing structure 10, the discontinuous island-like structures may be converted into a continuous structure. A thickness of the continuous structure, which is transferred from the discontinuous island-like structure, may be varied depending on a kind of metal. For example, when the preliminary embossing structure 110 is formed using tantalum, a continuous structure may begin to form when the preliminary embossing structure 110 has a thickness of about 11 Å.

Referring to FIG. 3C, a conductive layer 115 may be formed on the preliminary embossing structure 110. The conductive layer 115 may be formed by a CVD process, an atomic layer deposition (ALD) process, a sputtering process and/or any other suitable process. The preliminary embossing structure 110 and the conductive layer 115 may be patterned to form a gate electrode 140 (see FIG. 3E) in a subsequent process. The conductive layer 115 may be formed using a different material according to the transistor. The gate electrode 140 proper for an NMOS transistor may have a work function of about 4.1 eV to about 4.7 eV. In example embodiments, the preliminary embossing structure 110 may be formed using a metal or a metal compound (e.g., a metal nitride, a metal carbide and/or a metal carbonitride) having a work function of about 4.4 eV to about 4.7 eV. The conductive layer 115 may be formed using polysilicon doped with first impurities on the preliminary embossing structure 110. The gate electrode 140 may have a work function of about 4.1 eV to about 4.7 eV, which is proper for the NMOS transistor according to a concentration of the first impurities.

In other example embodiments, the preliminary embossing structure 110 may be formed using a metal or a metal compound (e.g., a metal nitride, a metal carbide and/or a metal carbonitride) having a work function of about 4.4 eV to about 4.7 eV. The conductive layer 115 may be formed using a metal or a metal compound (e.g., a metal nitride, a metal carbide and/or a metal carbonitride) having a work function of about 3 eV to about 4.6 eV. When the gate electrode 140 is formed by the above methods, the preliminary embossing structure 110 and the conductive layer 115 may be formed using various materials according to a desirable semiconductor device and manufacturing processes of the semiconductor device. The gate electrode 140 having a desirable work function may be formed by controlling a thickness of the preliminary embossing structure 110.

The gate electrode for a PMOS transistor may have a work function of about 4.7 eV to about 5.2 eV. In example embodiments, the preliminary embossing structure 110 may be formed using a metal or a metal compound (e.g., a metal nitride, a metal carbide and/or a metal carbonitride) having a work function of about 4.4 eV to about 4.7 eV. The conductive layer 115 may be formed using polysilicon doped with second impurities on the preliminary embossing structure 110. The gate electrode 140 may have a work function of about 4.7 eV to about 5.2 eV, which is proper for the PMOS transistor according to a concentration of the second impurities. In other example embodiments, the preliminary embossing structure 110 may be formed using a metal or a metal compound (e.g., a metal nitride, a metal carbide and/or a metal carbonitride) having a work function of about 4.4 eV to about 4.7 eV. The conductive layer 115 may be formed using a metal or a metal compound (e.g., a metal nitride, a metal carbide and/or a metal carbonitride) having a work function of about 4.6 eV to about 6 eV.

Referring to FIG. 3D, a nitride layer 107 may be further formed between the gate insulation layer 105 and the preliminary embossing structure 110 in accordance with other example embodiments. When the conductive layer 115 is formed using polysilicon doped with impurities on the gate insulation layer 105 including a high-k material, Fermi level pinning phenomenon may occur. Impurities in the conductive layer 115 may penetrate into the substrate 100. The nitride layer 107 may serve to retard or prevent the Fermi level pinning phenomenon and a penetration of the impurities into the substrate 100.

Referring to FIG. 3E, a mask layer may be formed on the conductive layer 115. The mask layer may be patterned by a photolithography process to form a gate mask 120. The conductive layer 115 may be patterned using the gate mask 120 as an etching mask to form a conductive layer pattern 125. The preliminary embossing structure 110 may be patterned to form an embossing structure 130. The gate electrode 140 including the conductive layer pattern 125 and the embossing structure 130 may be formed. The gate insulation layer 105 may be patterned to form a gate insulation layer pattern 135. A gate structure 145 may be formed on the substrate 100. The gate structure 145 may include the gate electrode 140 including the conductive layer pattern 125 and the embossing structure 130, the gate insulation layer pattern 135 and the gate mask 120. In example embodiments, a spacer 150 may be further formed on a sidewall of the gate structure 145.

Impurities may be implanted on surface portions of the substrate 100 adjacent to the gate structure 145 using the gate structure 145 as an implantation mask, thereby forming impurity regions 155. The impurities may include N-type impurities (e.g., phosphorus (P)) or P-type impurities (e.g., boron (B)). A transistor including the gate structure 145 and the impurity regions 155 may be formed on the substrate 100.

Semiconductor Device and Method of Manufacturing the Semiconductor Device

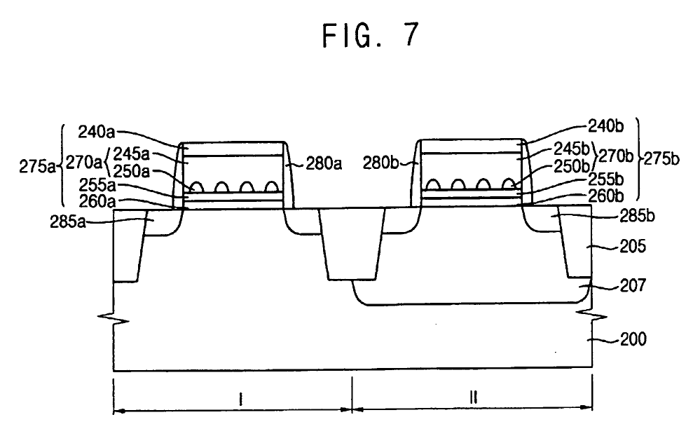

FIG. 7 is a diagram illustrating a semiconductor device including a complementary metal-oxide semiconductor (CMOS) transistor in accordance with example embodiments. Referring to FIG. 7, an active region may be defined on a substrate 200 by an isolation layer 205. The substrate 200 may include a silicon wafer and/or a silicon-on-insulator (SOI) substrate. The substrate 200 may be doped with P-type impurities. A first conductive region I may be formed in a first portion of the active region of substrate 200. A second conductive region II may be formed in a second portion of the active region of substrate 200. The second conductive region II may include an N-type well 207 doped with N-type impurities. In example embodiments, an NMOS transistor may be formed on the first conductive region I and a PMOS transistor may be formed on the second conductive region II.

The first conductive region I may include at least one NMOS transistor thereon. The NMOS transistor may have an effective work function of about 4.1 eV to about 4.6 eV. The second conductive region II may include at least one PMOS transistor thereon. The PMOS transistor may have an effective work function of about 4.7 eV to about 5.2 eV. The NMOS transistor may include a first gate structure 275a, a first spacer 280a and first impurity regions 285a. The first gate structure 275a may include a first gate insulation layer pattern 260a, a first nitride layer pattern 255a, a first gate electrode 270a and a first gate mask pattern 240a. The first gate electrode 270a may include a first embossing structure 250a and a first conductive layer pattern 245a. The first embossing structure 250a may include discontinuous island-like structures. The first spacer 280a may be formed on a sidewall of the first gate structure 275a. The first impurity regions 285a may be formed in surface portions of the substrate 200 adjacent to the first gate structure 275a.

In example embodiments, the first embossing structure 250a may include a metal or a metal compound (e.g., a metal nitride, a metal carbide and/or a metal carbonitride) having a work function of about 4.4 eV to about 4.7 eV. The first conductive layer pattern 245a may include polysilicon doped with first conductive impurities. Examples of the metal having the work function of about 4.4 eV to about 4.7 eV may include copper (Cu), germanium (Ge), ruthenium (Ru), tungsten (W), chromium (Cr) and/or any other suitable metal.

In other example embodiments, the first embossing structure 250a may include a metal or a metal compound (e.g., a metal nitride, a metal carbide and/or a metal carbonitride) having a work function of about 4.4 eV to about 4.7 eV. The first conductive layer pattern 245a may include a metal or a metal compound (e.g., a metal nitride, a metal carbide and/or a metal carbonitride) having a work function of about 3 eV to about 4.6 eV. Examples of the metal having the work function of about 3 eV to about 4.6 eV may include iron (Fe), magnesium (Mg), cobalt (Co), aluminum (Al), titanium (Ti), zirconium (Zr), hafnium (Hf), lead (Pb) and/or any other suitable metal.

In still other example embodiments, the first embossing structure 250a may include a metal or a metal compound (e.g., a metal nitride, a metal carbide and/or a metal carbonitride) having a work function of about 3 eV to about 5 eV. The first conductive layer pattern 245a may include a metal or a metal compound (e.g., a metal nitride, a metal carbide and/or a metal carbonitride) having a work function of about 1.5 eV to about 4.6 eV.

The PMOS transistor may include a second gate structure 275b, a second spacer 280b and second impurity regions 285b. The second gate structure 275b may include a second gate insulation layer pattern 260b, a second nitride layer pattern 255b, a second gate electrode 270b and a second gate mask pattern 240b. The second gate electrode 270b may include a second embossing structure 250b and a second conductive layer pattern 245b. The second embossing structure 250b may include discontinuous island-like structures. The second spacer 280b may be formed on a sidewall of the second gate structure 275b. The second impurity regions 285b may be formed in surface portions of the substrate 200 adjacent to the second gate structure 275b. In example embodiments, the second embossing structure 250b may include a metal or a metal compound (e.g., a metal nitride, a metal carbide and/or a metal carbonitride) having a work function of about 4.4 eV to about 4.7 eV. The second conductive layer pattern 245b may include polysilicon doped with second conductive impurities. The second gate electrode 270b may have a work function of about 4.7 eV to about 5.2 eV, which is proper for the PMOS transistor by controlling a concentration of the second conductive impurities.

In other example embodiments, the second embossing structure 250b may include a metal or a metal compound (e.g., a metal nitride, a metal carbide and/or a metal carbonitride) having a work function of about 4.4 eV to about 4.7 eV. The second conductive layer pattern 245b may include a metal or a metal compound (e.g., a metal nitride, a metal carbide and/or a metal carbonitride) having a work function of about 4.6 eV to about 6 eV. In other example embodiments, the second embossing structure 250b may include a metal or a metal compound (e.g., a metal nitride, a metal carbide and/or a metal carbonitride) having a work function of about 3 eV to about 5 eV. The second conductive layer pattern 245b may include a metal or a metal compound (e.g., a metal nitride, a metal carbide and/or a metal carbonitride) having a work function of about 4.6 eV to about 6.5 eV.

According to example embodiments, the semiconductor device may include the first and the second embossing structures 250a and 250b and the first and the second conductive layer patterns 245a and 245b. The second embossing structures 250a and 250b and the first and the second conductive layer patterns 245a and 245b may include various materials having proper work functions according to a desirable semiconductor device, respectively. The semiconductor device may include CMOS transistors including the NMOS transistor on the first conductive region I and the PMOS transistor on the second conductive region II.

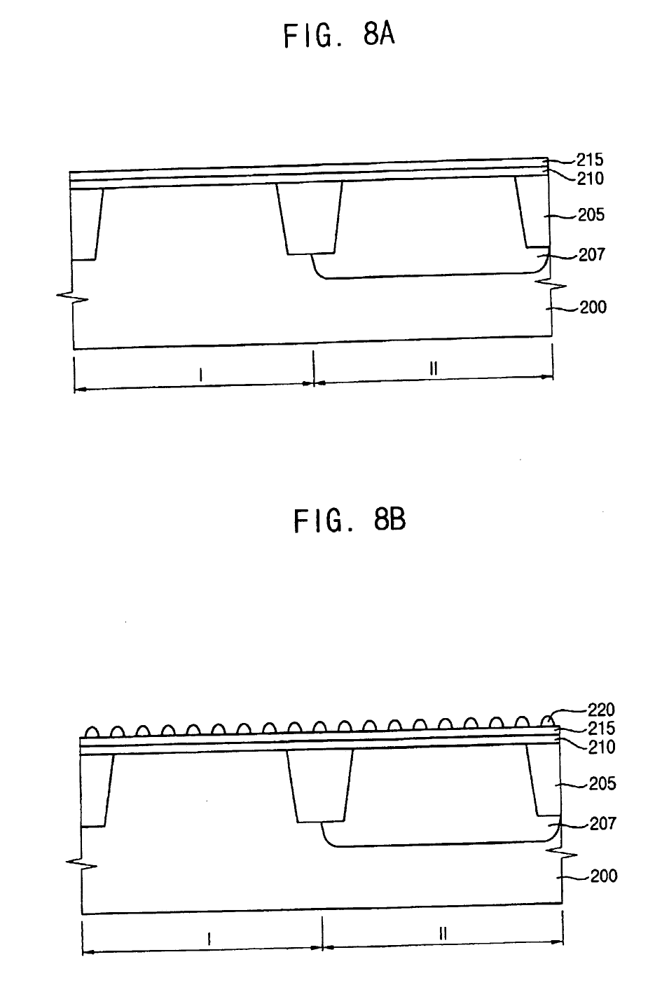

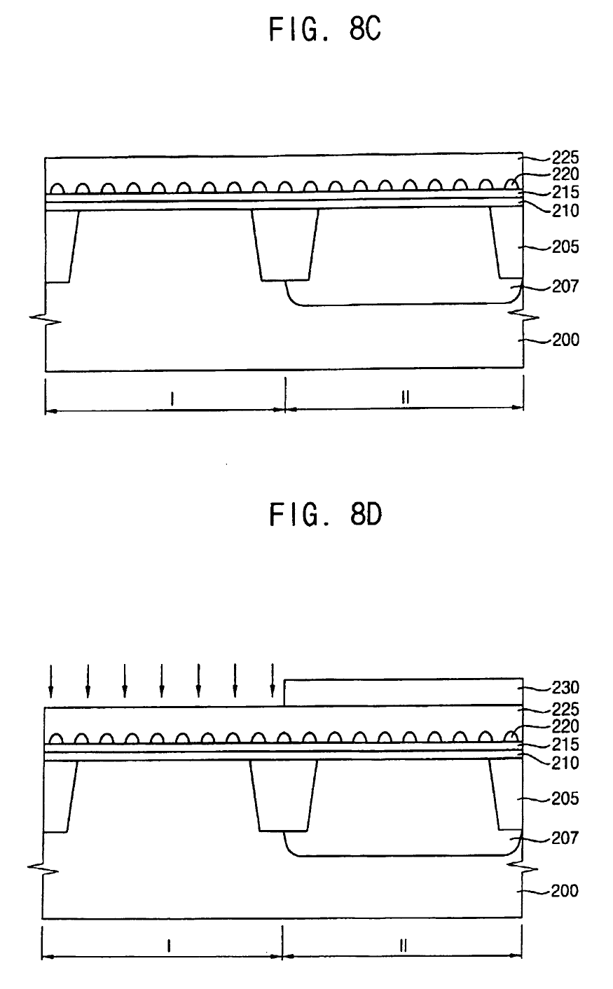

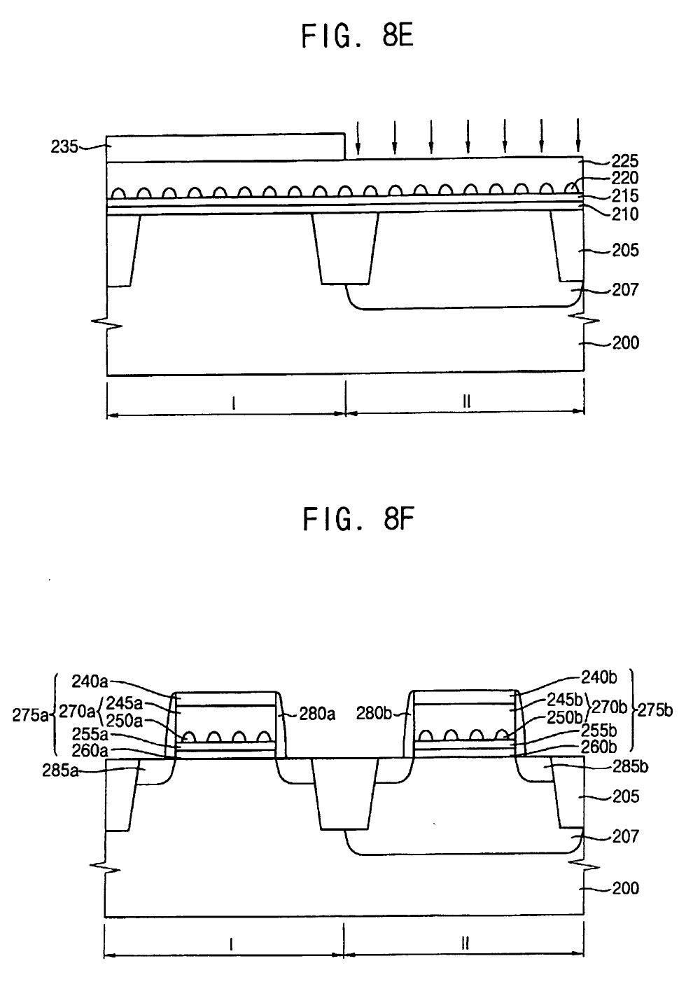

FIGS. 8A to 8F are diagrams illustrating a method of manufacturing a semiconductor device including a CMOS transistor in accordance with example embodiments. Referring to FIG. 8A, an isolation layer 205 may be formed in a substrate 200 by an isolation process (e.g., a local oxidation of silicon (LOCOS) process, a shallow trench isolation (STI) process and/or any other suitable process) to define an active region and a field region. The substrate 200 may include a silicon wafer or a silicon-on-insulator (SOI) substrate. In example embodiments, the substrate 200 may include polysilicon doped with P-type impurities.

N-type impurities may be implanted in a portion of the active region to form an N-type well 207. A second conductive region II including the N-type well 207 may be defined in the substrate 200. The active region doped with the P-type impurities may be defined as a first conductive region I. In example embodiments, an NMOS transistor may be formed on the first conductive region I and a PMOS transistor may be formed on the second conductive region II.

A gate insulation layer 210 may be formed on the substrate 200 where the first and the second conductive regions I and II are formed therein. In example embodiments, the gate insulation layer 210 may be formed using silicon oxide. The gate insulation layer 210 may be formed by a rapid thermal oxidation process, a furnace thermal oxidation process, a plasma oxidation process and/or any suitable process. In other example embodiments, the gate insulation layer 210 may be formed using a high-k material, for example, a metal oxide including hafnium oxide, zirconium oxide, tantalum oxide, aluminum oxide, titanium oxide and/or any other suitable metal oxide. The gate insulation layer 210 may be formed by a CVD process, an ALD process and/or any other suitable process. When the gate insulation layer 210 is formed using the high-k material, a nitride layer 215 may be further formed on the gate insulation layer 210. The nitride layer 215 may be formed using a nitride (e.g., silicon nitride). The nitride layer 215 may be formed by an ALD process and/or a low pressure CVD (LPCVD) process.

When a conductive layer including polysilicon doped with impurities is formed on the gate insulation layer 210 including a high-k material, the conductive layer may have a Fermi level different from that of the conductive layer formed on a silicon oxide layer. A MOS transistor having a desirable work function may be more difficult to form. The nitride layer 215 formed on the gate insulation layer 210 may relieve the Fermi level pining phenomenon. The nitride layer 215 may serve as a barrier layer for retarding, or preventing, the penetration of impurities (e.g., boron (B)) into the substrate 200. In other example embodiments, the nitride layer 215 may not be formed.

Referring to FIG. 8B, a preliminary embossing structure 220 may be formed on the nitride layer 215. In example embodiments, the preliminary embossing structure 220 may be formed by an electron beam (e-beam) evaporation deposition process. The e-beam evaporation deposition process may be performed by spraying a material on a rotating substrate 200 in a chamber using an electron gun. The material may be deposited in a more pure form on the substrate 200 by the e-beam evaporation deposition process.

The preliminary embossing structure 220 may include discontinuous island-like structures. The preliminary embossing structure 220 may be patterned to form a gate electrode of a transistor with a conductive layer formed on the preliminary embossing structure 220. According to example embodiments, the semiconductor device may include an NMOS transistor in the first conductive region I and a PMOS transistor in the second conductive region II. The NMOS transistor may have an effective work function of about 4.1 eV to about 4.6 eV. The PMOS transistor may have an effective work function of about 4.7 eV to about 5.2 eV. Work functions of the NMOS transistor and the PMOS transistor may be controlled by the preliminary embossing structure 220. For example, when the preliminary embossing structure 220 includes the discontinuous island-like structures at an early stage of deposition, a work function of the preliminary embossing structure 220 may be changed according to the size and density of the island-like structures.

In example embodiments, the preliminary embossing structure 220 may be formed on the first and the second conductive regions I and II. The preliminary embossing structure 220 may be formed using a mid-gap work function metal having a work function of about 4.4 eV to about 4.7 eV. The mid-gap work function metal may include copper (Cu), germanium (Ge), ruthenium (Ru), tungsten (W), chromium (Cr) and/or any other suitable metal.

In other example embodiments, the preliminary embossing structure 220 may be formed using a metal or a metal compound having a work function of about 4.4 eV to about 4.7 eV. The metal compound may include titanium nitride, tantalum nitride, tantalum carbide, molybdenum nitride, hafnium nitride, tungsten nitride, molybdenum carbide, hafnium carbide, tungsten carbide, tantalum carbonitride, tungsten carbonitride, tantalum silicon nitride, molybdenum silicon nitride, hafnium silicon nitride, tungsten silicon nitride, titanium aluminum nitride, tantalum aluminum nitride, molybdenum aluminum nitride, tantalum aluminum carbonitride, titanium aluminum carbonitride and/or any other suitable material.

The metal compound may have a work function of about 4.4 eV to about 4.7 eV according to a composition ratio or a deposition process of the metal compound. The deposition process may include a CVD process, a sputtering process, an ALD process, a PLD process and/or any other suitable process.

Referring to FIG. 8C, a polysilicon layer 225 may be formed on the preliminary embossing structure 220, which may be formed on the first and the second conductive regions I and II. The polysilicon layer 225 may be formed by a CVD process, a sputtering process, an ALD process, a PLD process and/or any other suitable process.

Referring to FIG. 8D, a first ion implantation mask 230 may be formed on the polysilicon layer 225 on the second conductive region II. First conductive impurities may be doped into the polysilicon layer 225 on the first conductive region I using the first ion implantation mask 230 as an implantation mask. The first conductive impurities may include boron (B), boron difluoride (BF₂) and/or any other suitable material. The polysilicon layer 225 on the first conductive region I may include the first conductive impurities.

Referring to FIG. 8E, the first ion implantation mask 230 may be removed from the substrate 200 by a chemical mechanical polishing (CMP) process, an etch back process and/or a combination process of CMP and etch back. A second ion implantation mask 235 may be formed on the polysilicon layer 225 on the first conductive region I. Second conductive impurities may be doped into the polysilicon layer 225 on the second conductive region II using the second ion implantation mask 235 as an implantation mask. The second conductive impurities may include phosphorus (P). The polysilicon layer 225 on the second conductive region II may include the second conductive impurities. The second ion implantation mask 235 may be removed from the substrate 200 by a CMP process, an etch back process and/or a combination process of CMP and etch back.

Referring to FIG. 8F, a mask layer may be formed on the polysilicon layer 225 doped with the first and the second conductive impurities. The mask layer may serve as a mask for patterning the polysilicon layer 225, the preliminary embossing structure 220, the nitride layer 215 and the gate insulation layer 210. The mask layer may serve as an etch stop layer in a subsequent process. The mask layer may be patterned by a photolithography to form first and second gate mask patterns 240a and 240b. The first gate mask pattern 240a may be formed to mask a region where a first gate structure 275a on the first conductive region I is formed. The second gate mask pattern 240b may be formed to mask a region where a second gate structure 275b on the second conductive region II is formed.

The polysilicon layer 225, the preliminary embossing structure 220, the nitride layer 215 and the gate insulation layer 210 may be patterned using the first and the second gate mask patterns 240a and 240b as etching masks, respectively. A first gate structure 275a may be formed on the first conductive region I. The first gate structure 275a may include a first gate mask pattern 240a, a first gate electrode 270a including a first conductive layer pattern 245a and a first embossing structure 205a, a first nitride layer pattern 255a and a first gate insulation layer pattern 260a. Simultaneously, a second gate structure 275b may be formed on the second conductive region II. The second gate structure 275b may include a second gate mask pattern 240b, a second gate electrode 270b including a second conductive layer pattern 245b and a second embossing structure 205b, a second nitride layer pattern 255b and a second gate insulation layer pattern 260b.

First impurities may be implanted into the active region adjacent to the first gate structure 275a using the first gate structure 275a as an ion implantation mask. Second impurities may be implanted into the active region adjacent to the second gate structure 275b using the second gate structure 275b as an ion implantation mask. An insulation layer may be formed to cover the first and the second gate structures 275a and 275b. The insulation layer may be formed using silicon oxide, silicon nitride, silicon carbonitride and/or any other suitable material. The insulation layer may be anisotropically etched to form a first spacer 280a on a sidewall of the first gate structure 275a. Simultaneously, a second spacer 280b may be formed on a sidewall of the second gate structure 275b.

First impurities, having a high concentration, may be implanted in the active region adjacent to the first gate structure 275a using the first gate structure 275a and the first spacer 280a as ion implantation masks. First impurity regions 285a may be formed in the substrate 200 adjacent to the first gate structure 275a. Second impurities having a high concentration may be implanted into the active region adjacent to the second gate structure 275b using the second gate structure 275b and the second spacer 280b as ion implantation masks. Second impurity regions 285b may be formed in the substrate 200 adjacent to the second gate structure 275b.

An NMOS transistor including the first gate electrode 270a and a PMOS transistor including the second gate electrode 270b may be formed on the substrate 200, respectively. The first gate electrode 270a may have a work function of about 4.4 eV to about 4.7 eV and the second gate electrode 270b may have a work function of about 4.7 eV to about 5.2 eV.

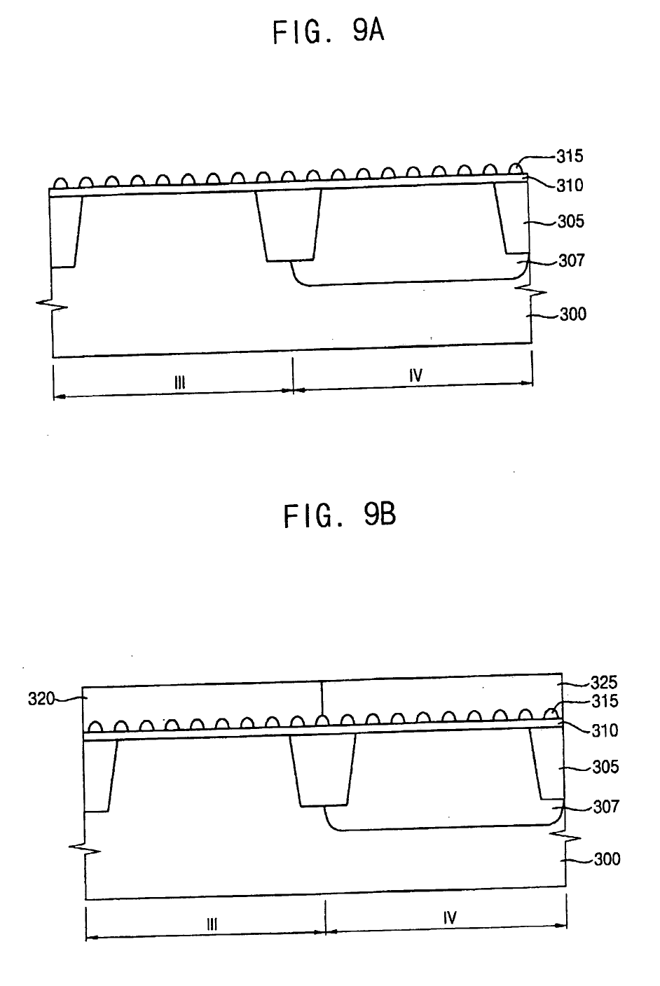

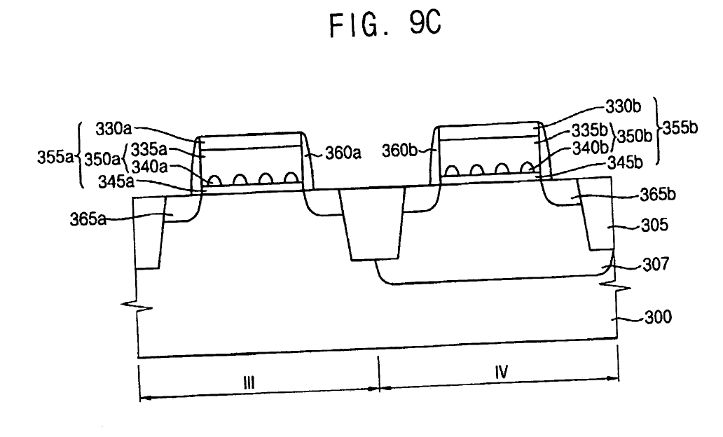

FIGS. 9A to 9C are diagrams illustrating a method of manufacturing a semiconductor device including a CMOS transistor in accordance with example embodiments.

Referring to FIG. 9A, an isolation layer 305 may be formed in a substrate 300 by an isolation process (e.g., an LOCOS process, an STI process and/or any other suitable process) to define an active region and a field region. In example embodiments, the substrate 300 may include polysilicon doped with P-type impurities. N-type impurities may be implanted in a portion of the active region to form an N-type well 307. A second conductive region IV including the N-type well 307 may be defined in the substrate 300. The active region doped with the P-type impurities may be defined as a first conductive region III. In example embodiments, an NMOS transistor may be formed on the first conductive region III and a PMOS transistor may be formed on the second conductive region IV. A gate insulation layer 310 may be formed on the substrate 300 where the first and the second conductive regions III and IV are formed therein. The gate insulation layer 310 may be formed using silicon oxide or a metal oxide.

A preliminary embossing structure 315 may be formed on the gate insulation layer 310. The preliminary embossing structure 315 may be formed by an e-beam evaporation deposition process. In example embodiments, the preliminary embossing structure 315 may be formed using a mid-gap work function metal having a work function of about 4.4 eV to about 4.7 eV. In other example embodiments, the preliminary embossing structure 315 may be formed using a metal compound having a work function of about 4.4 eV to about 4.7 eV. The metal compound may have a work function of about 4.4 eV to about 4.7 eV according to a composition ratio or a deposition process of the metal compound. The deposition process may include a CVD process, a sputtering process, an ALD process, a PLD process and/or any other suitable process. The preliminary embossing structure 315 may include discontinuous island-like structures. The preliminary embossing structure 315 may be patterned to form a gate electrode of a transistor with a conductive layer formed on the preliminary embossing structure 315.

According to example embodiments, the semiconductor device may include an NMOS transistor formed on the first conductive region III and a PMOS transistor formed on the second conductive region IV. The NMOS transistor may have an effective work function of about 4.1 eV to about 4.6 eV. The PMOS transistor may have an effective work function of about 4.7 eV to about 5.2 eV. When the preliminary embossing structure 315 includes the discontinuous island-like structures at an early stage of deposition, a work function may be changed according to the size and the density of the island-like structures.

Referring to FIG. 9B, a first conductive layer 320 may be formed on the preliminary embossing structure 315 on the first and the second conductive regions III and IV. The first conductive layer 320 may be formed using a metal or a metal compound having a work function of about 3 eV to 4.6 eV. The metal compound may have a work function of about 3 eV to about 4.6 eV according to a composition ratio or a deposition process (e.g., a CVD process, a sputtering process, an ALD process, a PLD process and/or any other suitable process). The first conductive layer 320 formed on the second conductive region IV may be removed by a photolithography process to expose the preliminary embossing structure 315 on the second conductive region IV.

A second conductive layer 325 may be formed to cover the preliminary embossing structure 315 on the second conductive region IV. In example embodiments, the second conductive layer 325 may be formed using a metal having a work function of about 4.6 eV to about 6 eV. The metal having the work function of about 4.6 eV to about 6 eV may include nickel (Ni), platinum (Pt), palladium (Pd), rhodium (Ru), iridium (Ir), selenium (Se) and/or any other suitable metal. In other example embodiments, the second conductive layer 325 may be formed using a metal compound having a work function of about 4.6 eV to about 6 eV. The metal compound may have a work function of about 4.6 eV to about 6 eV according to a composition ratio or a deposition process (e.g., a CVD process, a sputtering process, an ALD process, a PLD process and/or any other suitable process). The second conductive layer 325 formed on the first conductive layer 325 may be removed from the substrate 300. The first conductive layer 320 may remain on the first conductive region III and the second conductive layer 325 may remain on the second conductive region IV.

Referring to FIG. 9C, a mask layer may be formed on the first and the second conductive layers 320 and 325. The mask layer may be patterned by a photolithography process to form a first and a second gate mask patterns 330a and 330b on the first and the second conductive regions III and IV, respectively. The first gate mask pattern 330a may be formed to mask a region where a first gate structure 355a on the first conductive region III is formed. The second gate mask pattern 330b may be formed to mask a region where a second gate structure 355b on the second conductive region IV is formed. The first conductive layer 320, the preliminary embossing structure 315 and the gate insulation layer 310 may be successively patterned using the first gate mask pattern 330a as an etching mask. The first gate structure 355a may be formed on the first conductive region III. The first gate structure 355a may include the first gate mask pattern 330a, a first gate electrode 350a including a first conductive layer pattern 335a and a first embossing structure 340a and a first gate insulation layer pattern 345a.

The second conductive layer 320, the preliminary embossing structure 315 and the gate insulation layer 310 may be successively patterned using the second gate mask pattern 330b as an etching mask. The second gate structure 355b may be formed on the second conductive region IV. The second gate structure 355b may include the second gate mask pattern 330b, a second gate electrode 350b including a second conductive layer pattern 335b and a second embossing structure 340b and a second gate insulation layer pattern 345b. First impurities may be implanted in the active region adjacent to the first gate structure 355a using the first gate structure 355a as an ion implantation mask, thereby forming a first lightly doped region. Second impurities may be implanted in the active region adjacent to the second gate structure 355b using the second gate structure 355b as an ion implantation mask, thereby forming a second lightly doped region. A first spacer 360a may be formed on a sidewall of the first gate structure 355a. Simultaneously, a second spacer 360b may be formed on a sidewall of the second gate structure 355b.

First impurities having a high concentration may be implanted in the active region adjacent to the first gate structure 355a using the first gate structure 355a and the first spacer 360a as ion implantation masks. First impurity regions 365a may be formed in the substrate 300 adjacent to the first gate structure 355a. Second impurities having a high concentration may be implanted in the active region adjacent to the second gate structure 355b using the second gate structure 355b and the second spacer 360b as ion implantation masks. Second impurity regions 365b may be formed in the substrate 300 adjacent to the second gate structure 355b. An NMOS transistor including the first gate electrode 350a and a PMOS transistor including the second gate electrode 350b may be formed on the substrate 300, respectively. The first gate electrode 350a may have a work function of about 4.4 eV to about 4.7 eV and the second gate electrode 350b may have a work function of about 4.7 eV to about 5.2 eV.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed and that modifications to the disclosed example embodiments, as well as other example embodiments, are intended to be included within the scope of the appended claims. Example embodiments are defined by the following claims, with equivalents of the claims to be included therein.

What is claimed is:

1. A gate electrode comprising:
an embossing structure including a metal or a metal compound, the embossing structure having a first work function; and
a conductive layer pattern formed on the embossing structure, the conductive layer pattern having a second work function.

2. The gate electrode of claim 1, wherein the embossing structure includes discontinuous island-like structures.

3. The gate electrode of claim 1, wherein the gate electrode has a work function greater than the second work function and smaller than the first work function.

4. The gate electrode of claim 3, wherein the embossing structure includes at least one selected from the group consisting of copper (Cu), germanium (Ge), ruthenium (Ru), tungsten (W) and chromium (Cr).

5. The gate electrode of claim 4, wherein the conductive layer pattern includes polysilicon doped with N-type impurities.

6. The gate electrode of claim 4, wherein the conductive layer pattern includes at least one selected from the group consisting of iron (Fe), magnesium (Mg), cobalt (Co), aluminum (Al), titanium (Ti), zirconium (Zr), hafnium (Hf), lead (Pb), nickel (Ni), platinum (Pt), palladium (Pd), rhodium (Rh) and selenium (Se).

7. The gate electrode of claim 1, wherein the gate electrode has a work function greater than the first work function and smaller than the second work function.

8. The gate electrode of claim 7, wherein the embossing structure includes at least one selected from the group consisting of copper (Cu), germanium (Ge), ruthenium (Ru), tungsten (W) and chromium (Cr).

9. The gate electrode of claim 8, wherein the conductive layer pattern includes polysilicon doped with P-type impurities.

10. The gate electrode of claim 8, wherein the conductive layer pattern includes at least one selected from the group consisting of nickel (Ni), platinum (Pt), palladium (Pd), rhodium (Ru), iridium (Ir) and selenium (Se).

11. A method of forming a gate electrode comprising:
forming an embossing structure including a metal or a metal compound, the embossing structure having a first work function; and
forming a conductive layer pattern on the embossing structure, the conductive layer pattern having a second work function.

12. The method of claim 11, wherein the embossing structure is formed by an electron-beam (e-beam) evaporation deposition process.

13. The method of claim 11, wherein the embossing structure includes at least one selected from the group consisting of copper (Cu), germanium (Ge), ruthenium (Ru), tungsten (W) and chromium (Cr).

14. The method of claim 13, wherein the conductive layer pattern includes polysilicon with N-type impurities or polysilicon with P-type impurities.

15. The method of claim 13, wherein the conductive layer pattern includes at least one selected from the group consisting of iron (Fe), magnesium (Mg), cobalt (Co), aluminum (Al), titanium (Ti), zirconium (Zr), hafnium (Hf), lead (Pb), nickel (Ni), platinum (Pt), palladium (Pd), rhodium (Rh) and selenium (Se).

16. A transistor comprising:
a substrate;
a gate insulation layer pattern formed on the substrate;
a gate electrode according to claim 1; and
an impurity region formed in the substrate adjacent to the gate electrode.

17. A method of manufacturing a transistor comprising:
forming a gate insulation layer pattern on a substrate;
forming a gate electrode according to claim 11 on the gate insulation layer pattern; and
forming an impurity region by implantation impurities in the substrate adjacent to the gate electrode.

18. A semiconductor device comprising:
a substrate;
a first conductive region and a second conductive region formed on the substrate;
a first gate insulation layer pattern and a second gate insulation layer pattern formed on the first conductive region and the second conductive region, respectively; and
a first gate structure and a second gate structure, including the first and the second gate electrodes according to claim 1, formed on the first and the second gate insulation layer patterns.

19. The semiconductor device of claim 18, wherein embossing structures of the first and the second gate electrodes have a first work function and a third work function, and conductive layer patterns of the first and the second gate electrodes have a second work function and a fourth work function, respectively.

20. The semiconductor device of claim 19, wherein the first gate electrode has a work function in a range of the second work function to the first work function and wherein the second gate electrode has a work function in a range of the third work function to the fourth work function.

21. The semiconductor device of claim 18, wherein the conductive layer pattern of the first gate electrode includes polysilicon doped with N-type impurities and wherein the conductive layer pattern of the second gate electrode includes polysilicon doped with P-type impurities.

22. The semiconductor device of claim 18, wherein the first and the second gate insulation layer patterns include high-k materials.

23. The semiconductor device of claim 18, further comprising:
a first nitride layer pattern on the first gate insulation layer pattern and a second nitride layer pattern on the second gate insulation layer pattern.

24. The semiconductor device of claim 18, wherein the conductive layer pattern of the first gate electrode includes at least one selected from the group consisting of iron (Fe), magnesium (Mg), cobalt (Co), aluminum (Al), titanium (Ti), zirconium (Zr), hafnium (Hf) and lead (Pb).

25. The semiconductor device of claim 18, wherein the conductive layer pattern of the second gate electrode includes at least one selected from the group consisting of nickel (Ni), platinum (Pt), palladium (Pd), rhodium (Rh) and selenium (Se).

26. A method of manufacturing a semiconductor device, comprising:
forming a first conductive region and a second conductive region on a substrate;
forming a first gate insulation layer pattern and a second gate insulation layer pattern on the first and the second conductive regions, respectively; and
forming a first gate structure and a second gate structure, including a first gate electrode and a second gate electrode according to claim 11, on the first and the second gate insulation layer patterns.

27. The method of claim 26, wherein embossing structures of the first and the second gate electrodes have a first work function and a third work function, and conductive layer patterns of the first and the second gate electrodes have a second work function and a fourth work function, respectively.

28. The method of claim 27, wherein the first gate electrode has a work function greater than the second work function and smaller than the first work function, and wherein the second gate electrode has a work function greater than the third work function and smaller than the fourth work function.
